(19) United States
(12) Patent Application Publication
(10) Pub. No.: US 2020/0144090 A1
(43) Pub. Date: May 7, 2020

(54) PLACING TABLE AND SUBSTRATE PROCESSING APPARATUS

(71) Applicant: Tokyo Electron Limited, Tokyo (JP)

(72) Inventors: Toshiya Tsukahara, Kurokawa-gun (JP); Mitsuaki Sato, Kurokawa-gun (JP); Junichi Sasaki, Kurokawa-gun (JP); Namho Yun, Hwaseong-si (KR); Jisoo Suh, Hwaseong-si (KR)

(21) Appl. No.: 16/672,704

(22) Filed: Nov. 4, 2019

(30) Foreign Application Priority Data
Nov. 5, 2018 (JP) 2018-207908

(51) Int. Cl. H01L 21/683; H01J 37/32; H01L 21/687; H01L 21/67

(52) U.S. Cl. CPC H01L 21/6833; H01J 37/32642; H01J 37/32715; H01J 2237/334; H01L 21/68714; H01L 21/67248; H01J 2237/21; H01J 37/32467

(57) ABSTRACT

A placing table includes an edge ring disposed to surround a substrate; an electrostatic chuck having a first placing surface on which the substrate is placed and a second placing surface on which the edge ring is placed; and an elastic member placed at a position lower than the first placing surface within a gap between an inner circumferential surface of the edge ring and a side surface of the electrostatic chuck between the first placing surface and the second placing surface.

### CROSS-REFERENCE TO RELATED APPLICATION

This application claims the benefit of Japanese Patent Application No. 2018-207908 filed on Nov. 5, 2018, the entire disclosure of which is incorporated herein by reference.

### TECHNICAL FIELD

The various aspects and embodiments described herein pertain generally to a placing table and a substrate processing apparatus.

### BACKGROUND

For example, Patent Document 1 describes a placing table having a wafer placing portion on a top surface thereof and an annular peripheral portion extending to an outside of the wafer placing portion. A wafer as a processing target is placed on the wafer placing portion, and a focus ring is mounted on the annular peripheral portion. A gap is provided between facing sidewalls of an edge ring and an electrostatic chuck.

Patent Docume1: Japanese Patent Laid-open Publication No. 2008-244274

### SUMMARY

In one exemplary embodiment, a placing table includes an edge ring disposed to surround a substrate; an electrostatic chuck having a first placing surface on which the substrate is placed and a second placing surface on which the edge ring is placed; and an elastic member placed at a position lower than the first placing surface within a gap between an inner circumferential surface of the edge ring and a side surface of the electrostatic chuck between the first placing surface and the second placing surface.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating an example of a substrate processing apparatus according to an exemplary embodiment;

FIG. 2A to FIG. 2D are diagrams for describing deviation in a position of an edge ring caused by expansion/contraction due to a temperature variation;

FIG. 3A and FIG. 3B are diagrams for describing particle generation;

FIG. 4A to FIG. 4C are diagrams for describing the particle generation; and

FIG. 5 is a diagram illustrating an effect of positioning of the edge ring according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments will be described with reference to the accompanying drawings. In the specification and the drawings, substantially same parts will be assigned same reference numerals, and redundant description will be omitted.

[Overall Configuration of Substrate Processing Apparatus]

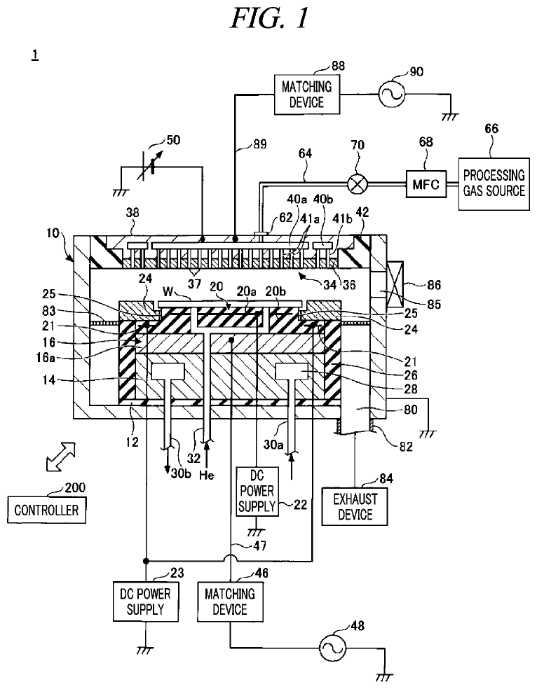

FIG. 1 is a diagram illustrating an example of a substrate processing apparatus 1 according to an exemplary embodiment. The substrate processing apparatus 1 according to the present exemplary embodiment is configured as a capacitively coupled parallel plate type processing apparatus, and includes a cylindrical processing vessel 10 made of, for example, aluminum having an anodically oxidized surface. The processing vessel 10 is grounded.

A column-shaped supporting table 14 is disposed at a bottom of the processing vessel 10 with an insulating plate 12 made of ceramics or the like therebetween. Provided on this supporting table 14 is a placing table 16 which is made of, by way of non-limiting example, aluminum. The placing table 16 includes an electrostatic chuck 20, a base 16a, an edge ring 24 and a sheet member 25. The electrostatic chuck 20 is configured to place thereon a wafer W as an example of a substrate. The electrostatic chuck 20 has a structure in which a first electrode 20a made of a conductive film is embedded in an insulating layer 20b, and a DC power supply 22 is connected to the first electrode 20a. The electrostatic chuck 20 may have a heater and be capable of performing a temperature control.

The conductive edge ring 24 made of, by way of example, silicon is disposed to surround the wafer W. The edge ring 24 is also called a focus ring. An annular insulator ring 26 made of, by way of example, quartz is disposed around the electrostatic chuck 20, the base 16a and the supporting table 14.

The electrostatic chuck 20 has a second electrode 21 which is buried therein at a position facing the edge ring 24. The second electrode 21 is connected to a DC power supply 23. The DC power supply 22 and the DC power supply 23 apply DC voltages individually. A central portion of the electrostatic chuck 20 generates an electrostatic force such as a Coulomb force by the voltage applied to the first electrode 20a from the DC power supply 22, so that the wafer W is attracted to and held by the electrostatic chuck 20 by this electrostatic force. Further, a peripheral portion of the electrostatic chuck 20 generates an electrostatic force such as a Coulomb force by the voltage applied to the second electrode 21 from the DC power supply 23, so that the edge ring 24 is attracted to and held by the electrostatic chuck 20 by this electrostatic force.

The sheet member 25 as an example of an elastic member is disposed between a side surface of the electrostatic chuck 20 and an inner circumferential surface of the edge ring 24. A plurality of sheet members 25 may be provided at a regular distance in a circumferential direction, or a single sheet member 25 may be provided in an annular shape. The sheet member 25 has a function of positioning the edge ring 24. The positioning of the edge ring 24 will be elaborated later.

Within the supporting table 14, a coolant path 28 is formed along a circumference, for example. A coolant of a preset temperature, for example, cooling water is supplied to be circulated in the coolant path 28 from an external chiller unit via pipelines 30a and 30b. A temperature of the wafer W on the placing table 16 is controlled by the temperature of the coolant. Further, a heat transfer gas, for example, a He gas from a heat transfer gas supply device is supplied into a gap between a top surface of the electrostatic chuck 20 and a rear surface of the wafer W through a gas supply line 32.

An upper electrode 34 is provided above the placing table 16, facing the placing table 16. A plasma processing space is provided between the upper electrode 34 and the placing table 16.

The upper electrode 34 is configured to close an opening of a ceiling of the processing vessel 10 with an insulating shield member 42 therebetween. The upper electrode 34 includes an electrode plate 36 forming a facing surface facing the placing table 16 and having a plurality of gas discharge holes 37; and an electrode supporting body 38 configured to support the electrode plate 36 in a detachable manner and made of a conductive material, for example, aluminum having an anodically oxidized surface. It is desirable that the electrode plate 36 is made of a silicon-containing material such as SiC or silicon. Gas diffusion spaces 40a and 40b are provided within the electrode supporting body 38, and a multiple number of gas through holes 41a and 41b extend in a downward direction from these gas diffusion spaces 40a and 40b to communicate with the gas discharge holes 37, respectively.

The electrode supporting body 38 is provided with a gas inlet opening 62 through which a gas is introduced into the gas diffusion spaces 40a and 40b. This gas inlet opening 62 is connected with a gas supply line 64, and the gas supply line 64 is connected to a processing gas source 66. The gas supply line 64 is equipped with a mass flow controller (MFC) 68 and an opening/closing valve 70 in sequence from an upstream side where the processing gas source 66 is provided. A processing gas is supplied from the processing gas source 66 into the gas diffusion spaces 40a and 40b through the gas supply line 64, and the processing gas is then discharged in a shower shape through the gas through holes 41a and 41b and the gas discharge holes 37.

The upper electrode 34 is connected with a variable DC power supply 50, and a DC voltage from the variable DC power supply 50 is applied to the upper electrode 34. A first high frequency power supply 90 is connected to the upper electrode 34 via a power feed rod 89 and a matching device 88. The first high frequency power supply 90 is configured to apply a HF (High Frequency) power to the upper electrode 34. The matching device 88 is configured to match an internal impedance of the first high frequency power supply 90 and a load impedance. Accordingly, plasma is formed from the gas in the plasma processing space. Further, the HF power from the first high frequency power supply 90 may be applied to the placing table 16.

In case of applying the HF power to the upper electrode 34, a frequency of the HF power needs to be in a range from 30 MHz to 70 MHz, for example, 40 MHz. In case of applying the HF power to the placing table 16, the frequency of the HF power needs to be in a range from 30 MHz to 70 MHz, for example, 60 MHz.

A second high frequency power supply 48 is connected to the placing table 16 via a power feed rod 47 and a matching device 46. The second high frequency power supply 48 is configured to apply a LF (Low Frequency) power to the placing table 16. The matching device 46 is configured to match an internal impedance of the second high frequency power supply 48 and the load impedance. Accordingly, ions are attracted into the wafer W on the placing table 16. The second high frequency power supply 48 outputs a high frequency power having a frequency ranging from 200 kHz to 13.56 MHz. A filter configured to pass a preset high frequency power to the ground may be connected to the placing table 16.

A frequency of the LF power is lower than the frequency of the HF power and may be in a range from 200 kHz to 40 MHz, for example, 12.88 MHz. A voltage or a current of each of the LF power and the HF power may be a continuous wave or a pulse wave. As stated above, the shower head configured to supply the gas also serves as the upper electrode 34, and the placing table 16 serves as a lower electrode.

An exhaust opening 80 is provided at the bottom of the processing vessel 10, and an exhaust device 84 is connected to this exhaust opening 80 via an exhaust line 82. The exhaust device 84 has a vacuum pump such as a turbo molecular pump and evacuates the processing vessel 10 to a required vacuum level. Further, a carry-in/out opening 85 for the wafer W is provided at a sidewall of the processing vessel 10, and this carry-in/out opening 85 is opened or closed by a gate valve 86.

An annular baffle plate 83 is provided between the annular insulator ring 26 and the sidewall of the processing vessel 10. The baffle plate 83 may be an aluminum member coated with ceramics such as, but not limited to, Y₂O₃.

To perform a preset processing such as an etching processing in the substrate processing apparatus 1 having the above-described configuration, the gate valve 86 is first opened, and the wafer W is carried into the processing vessel 10 through the carry-in/out opening 85 to be placed on the placing table 16. Then, a gas for the preset processing such as the etching processing is supplied from the processing gas source 66 into the gas diffusion spaces 40a and 40b at a preset flow rate, and this processing gas is supplied into the processing vessel 10 through the gas through holes 41a and 41b and the gas discharge holes 37. Further, the processing vessel 10 is evacuated by the exhaust device 84. Accordingly, an internal pressure of the processing vessel 10 is regulated to a set value ranging from, e.g., 0.1 Pa to 150 Pa.

In the state that the preset gas is introduced into the processing vessel 10 as described above, the HF power is applied to the upper electrode 34 from the first high frequency power supply 90. Further, the LF power is applied to the placing table 16 from the second high frequency power supply 48. Furthermore, the DC voltage is applied from the DC power supply 22 to the first electrode 20a to hold the wafer W on the placing table 16. Further, the DC voltage is applied from the DC power supply 23 to the second electrode 21 to hold the edge ring 24 on the placing table 16. The DC voltage from the variable DC power supply 50 may also be applied to the upper electrode 34.

The gas discharged from the gas discharge holes 37 of the upper electrode 34 are dissociated and ionized into plasma mainly by the HF power, and the preset processing such as the etching processing is performed on a processing target surface of the wafer W by radicals and/or ions in the plasma. Further, by applying the LF power to the placing table 16, the ions in the plasma are controlled to accelerate the preset processing such as the etching processing.

The substrate processing apparatus 1 is equipped with a controller 200 configured to control an overall operation of the apparatus. A CPU provided in the controller 200 implements the required plasma processing such as the etching processing according to recipes stored in a memory such as a ROM or a RAM. Control information of the apparatus for processing conditions such as a processing time, a pressure (gas exhaust), HF and LF high frequency powers and voltages, flows rates of various kinds of gases, and so forth may be set in the recipes. Furthermore, temperatures within the processing vessel (a temperature of the upper electrode, a temperature of the sidewall of the processing vessel, a temperature of the wafer W, a temperature of the electrostatic chuck, etc.), a temperature of the coolant outputted from the chiller, and so forth may be set in the recipes. These recipes including the processing conditions and programs may be stored in a hard disk or a semiconductor memory. Further, the recipes may be set to a preset position and read out while being stored in a portable computer-readable recording medium such as a CD-ROM, a DVD, or the like.

[Deviation of Edge Ring Position]

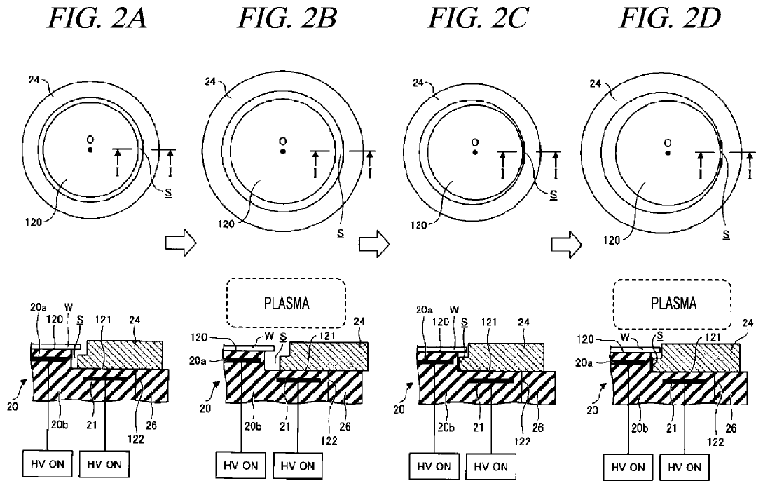

Now, deviation in a position of the edge ring 24 caused by expansion/contraction due to a temperature variation will be explained with reference to FIG. 2A to FIG. 2D. Upper drawings of FIG. 2A to FIG. 2D are plan views illustrating the placing surface 120 of the electrostatic chuck 20 on which the wafer W is placed and the edge ring 24, when viewed from top, and lower drawings of FIG. 2A to FIG. 2D are partially enlarged cross sectional views illustrating the electrostatic chuck 20 and the edge ring 24, taken along lines I-I of FIG. 2A to FIG. 2D, respectively.

The electrostatic chuck 20 has a placing surface 121 lower than the placing surface 120 on which the wafer W is placed. The edge ring 24 is placed on this placing surface 121. The placing surface 120 corresponds to a first placing surface on which the substrate is placed, and the placing surface 121 corresponds to a second placing surface on which the edge ring 24 is placed.

In the upper drawings of FIG. 2A to FIG. 2D, a positional relationship between the electrostatic chuck 20 and the edge ring 24 is indicated by positions of the placing surface 120 and the edge ring 24. FIG. 2A illustrates an initial state of the positions of the placing surface 120 and the edge ring 24. The edge ring 24 is positioned to be substantially concentric with a central axis O of the electrostatic chuck 20. Hereinafter, the positioning of the edge ring 24 to be substantially concentric with the central axis O of the electrostatic chuck 20 will be referred to as “aligning.” Here, a clearance S between the electrostatic chuck 20 and the edge ring 24 is controlled to be uniform.

FIG. 2B illustrates an example state where a temperature of the edge ring 24 is increased to a first temperature due to heat input from the plasma while performing the plasma processing on the wafer. Here, the edge ring 24 having a larger linear expansion coefficient than the electrostatic chuck 20 is expanded outwards, so that the clearance S is enlarged. Though the electrostatic chuck 20 is also expanded like the edge ring 24, the expansion of the electrostatic chuck 20 is smaller than that of the edge ring 24.

FIG. 2C illustrates an example state where the temperature of the edge ring 24 is set to a second temperature lower than the first temperature as the plasma is extinguished after the plasma processing. In this example, the edge ring 24 having the larger linear expansion coefficient than the electrostatic chuck 20 is contracted inwards, so that deviation of the clearance S occurs. Before and after the plasma processing shown in FIG. 2A to FIG. 2C, the edge ring 24 expands and contracts while being attracted to the electrostatic chuck 20 by a DC voltage HV applied thereto, and is deviated from the initial position (see FIG. 2A) where the edge ring 24 is substantially concentric with the electrostatic chuck 20. As a result, the edge ring 24 is moved to a position (see FIG. 2C) where it is not aligned with the electrostatic chuck 20. In the example shown in FIG. 2C, the clearance S is larger at the left and smaller at the right. The deviation illustrated in FIG. 2C is an example, and the deviation is not limited thereto.

If a next plasma processing is begun in the state of FIG. 2C, the edge ring 24 is expanded in the non-aligned state, and the clearance S becomes larger at the left, as illustrated in FIG. 2D. During the processing shown in FIG. 2A to FIG. 2D, the DC voltage HV is applied to the first electrode 20a and the second electrode 21, so that the wafer W is electrostatically attracted to the placing surface 120 and the edge ring 24 is electrostatically attracted to the placing surface 121. However, the edge ring 24 is deviated from the position where the edge ring 24 is substantially concentric with the electrostatic chuck 20 (the central axis O) as the processes of FIG. 2A to FIG. 2D are repeated.

As stated above, whenever the plasma processing is performed on each wafer, since the clearance S between the electrostatic chuck 20 and the edge ring 24 is not managed, particularly, an abnormal discharge called a micro arcing occurs at a place where the clearance S between the electrostatic chuck 20 and the edge ring 24 is narrow. Due to this abnormal discharge, a particle is generated from the gap between the electrostatic chuck 20 and the edge ring 24 and flies onto the wafer W, so that an adverse influence is affected upon the processing of the wafer W. As a result, a yield is reduced.

[Experimental Result 1]

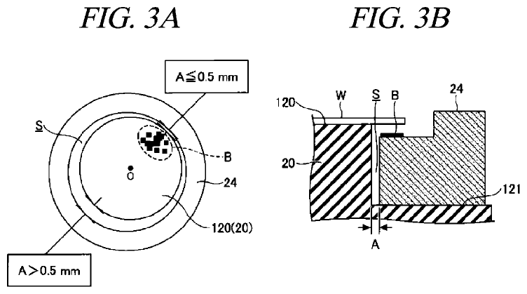

An experimental result 1 for the example of FIG. 2A to FIG. 2D will be discussed with reference to FIG. 3A and FIG. 3B. For example, as illustrated in FIG. 3B, a length of the clearance S between the inner circumferential surface of the edge ring 24 and the side surface of the electrostatic chuck 20 between the placing surface 120 and the placing surface 121 in a diametrical direction is referred to as a distance A. As shown in FIG. 3A, if the distance A is larger than 0.5 mm, no particle is generated from the gap between the electrostatic chuck 20 and the edge ring 24.

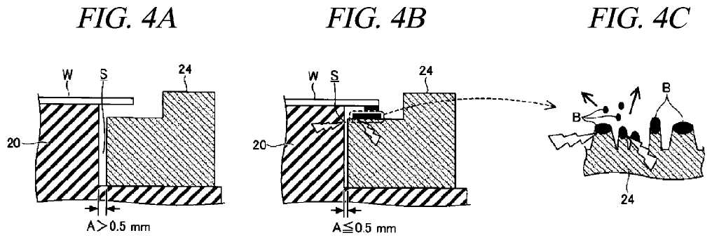

Meanwhile, as illustrated in a diagonally upper right side of FIG. 3A, if the distance A is equal to or less than 0.5 mm, a particle is generated from the gap between the electrostatic chuck 20 and the edge ring 24, so that a deposit B is generated. As a result of conducting an energy dispersive X-ray spectroscopy (EDX spectroscopy) for a composition of the deposit B, it is found out that a large amount of aluminum is contained in the deposit B. As can be seen from this, if the distance A is larger than 0.5 mm, the deposit B does not adhere near the clearance S and the micro arcing does not occur, as illustrated in FIG. 4A. Meanwhile, if the distance A is equal to or less than 0.5 mm, the deposit B adheres near the clearance S, as illustrated in FIG. 4B, and it is found out that this deposit B contains aluminum flown from the surface of the placing table 16. Thus, if the distance A is narrowed to equal to or less than 0.5 mm, an electric field of the high frequency power in the clearance S is strengthened. Furthermore, it is deemed that, due to the influence of the deposit B containing the aluminum, the micro arcing occurs near the clearance S, as illustrated in FIG. 4C, resulting in a defect.

Besides, it is also found out that if the edge ring 24 is made of SiC, the defect is more likely to occur, as compared to a case where the edge ring 24 is made of Si.

[Aligning Operation of Edge Ring]

In contrast, according to the present exemplary embodiment, an aligning operation of the edge ring 24 is enabled by the sheet member 25, thus suppressing the edge ring 24 from being deviated from the position where it is substantially concentric with the electrostatic chuck 20. Accordingly, the clearance S between the electrostatic chuck 20 and the edge ring 24 is managed. Thus, the abnormal discharge such as the micro arcing is suppressed, so that the particle generation is avoided.

[Experimental Result 2]

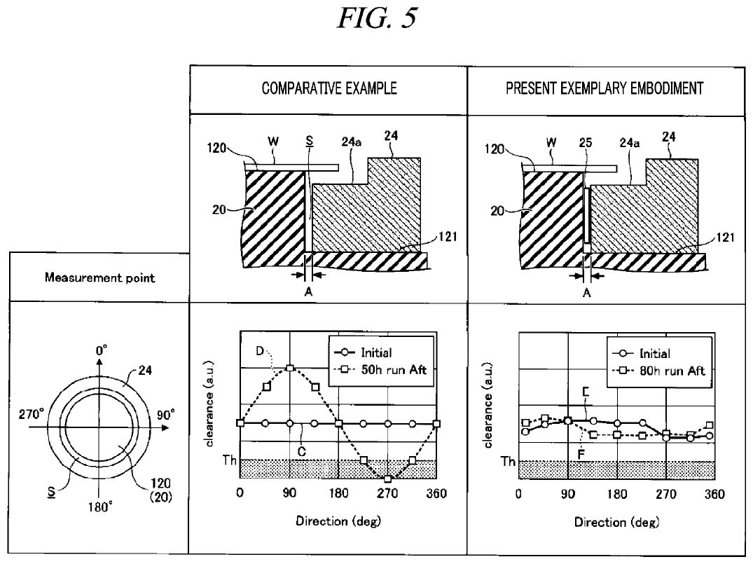

Referring to FIG. 5, an experimental result 2 upon the aligning operation of the edge ring 24 according to the present exemplary embodiment will be explained in comparison with a comparative example. The comparative example of FIG. 5 shows an example of an experiment result where nothing is provided in the clearance S between the edge ring 24 and the electrostatic chuck 20 as described in FIG. 2. The present exemplary embodiment of FIG. 5 illustrates an example of an experiment result where the sheet member 25 is provided in the clearance S between the edge ring 24 and the electrostatic chuck 20.

A horizontal axis of each graph indicates a measurement point of the clearance S between the edge ring 24 and the electrostatic chuck 20 at an interval of 45° with respect to a vertically upward direction of 0° (360°), a right transversal direction of 90°, a downward direction 180° and a left transversal direction of 270°. A measurement value is shown on a vertical axis indicating the clearance. The vertical axis indicates the measurement value of the clearance S at each angle in an arbitrary unit.

As a result of the experiments, in the comparative example, the clearance S in an initial state indicated by a line C is maintained uniform at each angle. Meanwhile, the clearance S after a plasma processing is performed for 50 hours is not managed uniform, as indicated by a line D. That is, the edge ring 24 is deviated from the electrostatic chuck 20 (central axis O) in the left-and-right direction.

In contrast, in the present exemplary embodiment, the clearance S in an initial state indicated by a line E is substantially maintained uniform at each angle, and the clearance S after the plasma processing is performed for 80 hours is also found to be substantially uniform at each angle, as indicated by a line F.

From the above experiments, in the placing table 16 according to the present exemplary embodiment, it is found out that the edge ring 24 is aligned with the electrostatic chuck 20 due to elasticity of the sheet member 25. Further, in the present exemplary embodiment, if a maximum value of the clearance S at each angle after the plasma processing is performed for a preset time (for example, 50 hours to 80 hours) is larger than a threshold value Th (0.5 mm), it is determined that the clearance S is within a tolerance range, that is, the edge ring 24 is aligned with the electrostatic chuck 20.

[Elastic Member]

The sheet member 25 is disposed at a position lower than the placing surface 120. Further, as shown in the present exemplary embodiment of FIG. 5, it is desirable that the sheet member 25 does not protrude from a bottom surface of a step portion 24a of the edge ring 24. If the sheet member 25 is protruded from the bottom surface of the step portion 24a of the edge ring 24, the sheet member 25 is exposed to the plasma, and may be easily consumed, having a short life span.

Here, however, if the sheet member 25 is disposed at an excessively lowered position, the sheet member 25 may be located in a lower portion of the clearance S, affecting an electrostatic attracting force of the electrostatic chuck 20. Thus, it is desirable to set the sheet member 25 after the edge ring 24 is attracted to the electrostatic chuck 20 by applying the DC voltage to the second electrode 21 of the electrostatic chuck 20.

The sheet member 25 described in the present exemplary embodiment is an example of an elastic member. The elastic member is not limited to the sheet type, and may be a film type or a spring type. If the sheet member 25 is of the spring type, the sheet member 25 may be a member having elasticity in a diametric direction (normal direction) or in a circumferential direction. In any case, the edge ring 24 can be aligned to be substantially concentric with the electrostatic chuck 20.

The number of the sheet member 25 may be one or plural. That is, a plurality of sheet members 25 may be equi-spaced in the circumferential direction, or a single sheet member 25 may be provided in a ring shape. Further, the elastic member may be made of a resin such as Polytetrafluoroethylene (PTFE). If the sheet member 25 is formed of the resin, a damage on the edge ring 24 and the electrostatic chuck 20 may be suppressed.

It is desirable that the sheet member 25 is made of the PTFE since the PTFE has plasma resistance. When the sheet member 25 is placed in the clearance S, however, a portion of the sheet member 25 located in the lower portion of the clearance S is not exposed to the plasma. Thus, only an upper portion of the sheet member 25, which is located in an upper portion of the clearance S when the sheet member 25 is placed in the clearance S, may be made of a material having the plasma resistance, while the rest portion of the sheet member 25 may be made of a resin not having the plasma resistance, or others.

A sheet member different from the sheet member 25 may be provided between the placing surface 121 and a rear surface of the edge ring 24. With this configuration, a heat transfer effect between the edge ring 24 and the electrostatic chuck 20 can be increased, and the amount of expansion/contraction of the edge ring 24 caused by the temperature variation can be reduced. Thus, the aligning of the edge ring 24 can be carried out efficiently.

Further, the application of the DC voltage HV to the second electrode 21 may be stopped after the edge ring 24 is changed from the first temperature to the second temperature which is different from the first temperature. Accordingly, the edge ring 24 is released from the electrostatic attracting force of the electrostatic chuck 20 and can be freely moved. As a result, the aligning of the edge ring 24 can be performed efficiently.

As stated above, with the sheet member 25 according to the present exemplary embodiment, the clearance S between the edge ring 24 and the electrostatic chuck 20 can be managed. Therefore, the occurrence of the abnormal discharge is suppressed, and the particle generation can be avoided.

The placing table and the substrate processing apparatus according to exemplary embodiment are not intended to be anyway limiting. Further, the exemplary embodiments may be changed and modified in various ways without departing from the scope of the present disclosure as claimed in the following claims. Unless contradictory, the disclosures in the various exemplary embodiments can be combined appropriately.

The substrate processing apparatus may be applicable to any of various types such as capacitively coupled plasma (CCP), inductively coupled plasma (ICP), radial line slot antenna (RLSA), electron cyclotron resonance plasma (ECR) and helicon wave plasma (HWP).

In the present disclosure, the wafer W is described as the example of the substrate. However, the substrate is not limited thereto and may be any of various substrates used in a FPD (Flat Panel Display), a print substrate, or the like.

According to the exemplary embodiment, a gap between facing sidewalls of the edge ring and the electrostatic chuck can be managed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A placing table, comprising:
an edge ring disposed to surround a substrate;
an electrostatic chuck having a first placing surface on which the substrate is placed and a second placing surface on which the edge ring is placed; and
an elastic member placed at a position lower than the first placing surface within a gap between an inner circumferential surface of the edge ring and a side surface of the electrostatic chuck between the first placing surface and the second placing surface.

2. The placing table of claim 1,
wherein the elastic member is of a sheet shape, a film shape or a spring shape.

3. The placing table of claim 1,
wherein the elastic member is made of a resin.

4. The placing table of claim 1,
wherein the elastic member is made of a material having plasma resistance.

5. The placing table of claim 1,
wherein the elastic member is a single elastic member arranged in a circumferential direction or the elastic member includes multiple elastic members arranged in the circumferential direction.

6. A substrate processing apparatus having a placing table,
wherein the placing table comprises:
an edge ring disposed to surround a substrate;
an electrostatic chuck having a first placing surface on which the substrate is placed and a second placing surface on which the edge ring is placed; and
an elastic member placed at a position lower than the first placing surface within a gap between an inner circumferential surface of the edge ring and a side surface of the electrostatic chuck between the first placing surface and the second placing surface.

7. The placing table of claim 2,
wherein the elastic member is made of a resin.

8. The placing table of claim 7,
wherein the elastic member is made of a material having plasma resistance.

9. The placing table of claim 8,
wherein the elastic member is a single elastic member arranged in a circumferential direction or the elastic member includes multiple elastic members arranged in the circumferential direction.
